(19) United States
(12) Patent Application Publication
(10) Pub. No.: US 2020/0365798 A1
(43) Pub. Date: Nov. 19, 2020

(54) DOUBLE-CHANNEL TOPOLOGICAL INSULATOR STRUCTURE, AND METHOD FOR GENERATING QUANTIZED ANOMALOUS HALL EFFECT

(71) Applicant: Tsinghua University, Beijing (CN)

(72) Inventors: KE HE, Beijing (CN); GAO-YUAN JIANG, Beijing (CN); QI-KUN XUE, Beijing (CN)

(73) Assignee: Tsinghua University, Beijing (CN)

(21) Appl. No.: 16/984,150

(22) Filed: Aug. 4, 2020

Related U.S. Application Data
(63) Continuation of application No. PCT/CN2018/093184, filed on Jun. 27, 2018.

(30) Foreign Application Priority Data
Feb. 5, 2018 (CN) 201810113605.X

(51) Int. Cl. H01L 43/12; H01L 43/02; H01L 43/08; H01L 43/10; H01F 41/32; H01F 10/193

(52) U.S. Cl. CPC H01L 43/12; H01L 43/02; H01F 10/1936; H01L 43/10; H01F 41/32; H01L 43/08

(57) ABSTRACT

The present application discloses a double-channel topological insulator structure includes an insulating substrate, a first topological insulator quantum well film, an insulating interlayer, and a second topological insulator quantum well film. The first topological insulator quantum well film, the insulating interlayer, and the second topological insulator quantum well film are orderly stacked on a surface of the insulating substrate. The first and second topological insulator quantum well films are separated by the insulating interlayer. The present application also discloses a method for making the double-channel topological insulator structure and a method for generating quantum spin Hall effect.

### CROSS-REFERENCE TO RELATED APPLICATIONS

This application claims priority of China Patent Applications No. 201810113605.X, filed on Feb. 5, 2018, entitled “DOUBLE-CHANNEL TOPOLOGICAL INSULATOR STRUCTURE, METHOD FOR MAKING THE SAME, AND METHOD FOR GENERATING QUANTIZED ANOMALOUS HALL EFFECT” in the China National Intellectual Property Administration, the content of which is hereby incorporated by reference. This application is a continuation under 35 U.S.C. § 120 of international patent application PCT/CN2018/093184 filed on Jun. 27, 2018, the content of which is also hereby incorporated by reference.

### FIELD

The present application relates to the field of condensed matter physics, and relates to a double-channel topological insulator structure, a method for making the same, and a method for generating quantized anomalous Hall effect.

### BACKGROUND

In 1879, American physicist Hall discovered that applying a magnetic field perpendicular to a direction of a current on a conductor having the current flowing therethrough would produce a potential difference in the direction perpendicular to the current and the magnetic field. This potential difference is caused by the Lorentz force, and is also called the Hall voltage. The Hall resistance can be obtained from the Hall voltage. Under the normal Hall effect, the Hall resistance and the applied magnetic field B have a linear relationship: Rxy=R_{H}*B, where R_{H} is the Hall coefficient. But immediately in 1880, Hall discovered that in magnetic materials, the Hall effect is much larger than that in nonmagnetic samples, and does not have a purely linear relationship with the magnetic field. This effect is called the anomalous Hall effect. In 1980, German physicists von Klitzing et al. discovered the integer Hall effect in a two-dimensional electron gas system under a strong magnetic field. In 1982, Chinese-American physicist Chee Tsui discovered the fractional Hall effect with fractional Hall conductance. In 2013, the team led by Academician Qikun Xue first achieved the quantum anomalous Hall effect under zero magnetic field in Cr-doped (Bi,Sb)₂Te₃, whose structure is a single-channel structure. When two topological insulator films are required to be connected in parallel or in series, the two topological insulator films respectively formed on different substrates have to be respectively provided.

### SUMMARY

A double-channel topological insulator structure includes an insulating substrate, a first topological insulator quantum well film, an insulating interlayer, and a second topological insulator quantum well film. The first topological insulator quantum well film, the insulating interlayer, and the second topological insulator quantum well film are orderly stacked on a surface of the insulating substrate. The first and second topological insulator quantum well films are separated by the insulating interlayer.

In an embodiment, the first topological insulator quantum well film, the insulating interlayer, and the second topological insulator quantum well film are lattice matched with each other, thereby cooperatively forming a heterojunction structure.

In an embodiment, the first topological insulator quantum well film has a first lattice constant, the insulating interlayer has a second lattice constant; the second topological insulator quantum well film has a third lattice constant; a ratio of the first lattice constant to the second lattice constant is between 1:1.1 and 1.1:1; and a ratio of the second lattice constant to the third lattice constant is between 1:1.1 and 1.1:1.

In an embodiment, the insulating interlayer is formed on a surface of the first topological insulator quantum well film by molecular beam epitaxy. A difference between a molecular beam epitaxy growth temperature of the insulating interlayer and a molecular beam epitaxy growth temperature of the first topological insulator quantum well film is less than or equal to 100° C.; a difference between the molecular beam epitaxy growth temperature of the insulating interlayer and a molecular beam epitaxy growth temperature of the second topological insulator quantum well film is less than or equal to 100° C.; and a difference between the molecular beam epitaxy growth temperatures of the first and second topological insulator quantum well films is less than or equal to 100° C.

In an embodiment, a material of the insulating interlayer is selected from wurtzite-structured CdSe, sphalerite-structured ZnTe, sphalerite-structured CdSe, sphalerite-structured CdTe, sphalerite-structured HgSe, or sphalerite-structured HgTe.

In an embodiment, the double-channel topological insulator structure further includes an insulating protective layer stacked on the second topological insulator quantum well film.

In an embodiment, a material of the insulating protective layer is selected from wurtzite-structured CdSe, sphalerite-structured ZnTe, sphalerite-structured CdSe, sphalerite-structured CdTe, sphalerite-structured HgSe, or sphalerite-structured HgTe.

In an embodiment, the first topological insulator quantum well film has a first coercive field, and the second topological insulator quantum well film has a second coercive field, the first coercive field is larger or smaller than the second coercive field.

In an embodiment, a material of the first topological insulator quantum well film is represented by a chemical formula M_{y}N_{z}(BiₓSb₁₋ₓ)_{2-y-z}Te₃, and a material of the second topological insulator quantum well film is represented by a chemical formula M′_{y′}N′_{z′}(Bi_{x′}Sb_{1-x′})_{2-y′-z′}Te₃, wherein M, M′, N, N′ are independently selected from one of Cr, Ti, Fe, Mn and V; 0<x<1, 0≤y, 0≤z, and 0<y+z<2; 0<x′<1, 0≤y′, 0≤z′ and 0<y′+z′<2; x≠x′ and/or y≠y′ and/or z≠z′.

In an embodiment, a material of the first topological insulator quantum well film is represented by a chemical formula M_{y}N_{z}(BiₓSb₁₋ₓ)_{2-y-z}Te₃, and a material of the second topological insulator quantum well film is represented by a chemical formula M′_{y′}N′_{z′}(Bi_{x′}Sb_{1-x′})_{2-y′-z′}Te₃, where M, M′, N, N′ are independently selected from one of Cr, Ti, Fe, Mn, and V, and M≠M′, and/or N≠N′; 0<x<1, 0≤y, 0≤z, and 0<y+z<2; 0<x′<1, 0≤y′, 0≤z′ and 0<y′+z′<2.

A method for making the double-channel topological insulator structure includes:

providing the insulating substrate in a molecular beam epitaxy reactor chamber;

growing the first topological insulator quantum well film by molecular beam epitaxy on a surface of the insulating substrate having the first temperature;

growing the insulating interlayer by molecular beam epitaxy on a surface of the first topological insulator quantum well film having the second temperature; and

growing the second topological insulator quantum well film by molecular beam epitaxy on a surface of the insulating interlayer having a third temperature.

In an embodiment, the first temperature is in a range from 150° C. to 250° C.; the second temperature is in a range from 50° C. to 350° C.; and the third temperature is in a range from 150° C. to 250° C.

A method for generating quantum spin Hall effect, and the method includes:

providing the double-channel topological insulator, the first topological insulator quantum well film having a first coercive field, and the second topological insulator quantum well film having a second coercive field, the first coercive field being larger or smaller than the second coercive field; and

applying a magnetic field which is ranged between the first coercive field and the second coercive field to the double-channel topological insulator.

In this application, two topological insulator quantum well films are separated by an insulating interlayer to form the double-channel topological insulator structure which is a monolithic member, making the device more compact and integrated. Each topological insulator quantum well film can be controlled independently as an independent electric element. The quantum spin Hall effect can be realized in the double-channel topological insulator structure having two different magnetically doped topological insulator quantum well films.

### BRIEF DESCRIPTION OF THE DRAWINGS

Implementations will now be described, by way of example only, with reference to the attached figures.

FIG. 1A to FIG. 1D show schematic views of a lattice structure of Sb₂Te₃ according to an embodiment of the present application, wherein FIG. 1A is a perspective view, FIG. 1B is a top view, FIG. 1C is a lattice structure diagram in the [110] direction, and FIG. 1D is a lattice structure diagram in the [210] direction.

FIG. 2A to FIG. 2D show schematic views of a lattice structure of CdSe according to an embodiment of the present application, wherein FIG. 2A is a perspective view, FIG. 2B is a top view, FIG. 2C is a lattice structure diagram in the [110] direction, and FIG. 2D is a lattice structure diagram in the [210] direction.

FIG. 3 A and FIG. 3B show schematic views of a lattice match between Sb₂Te₃ and CdSe, wherein FIG. 3A is a top view, and FIG. 3B is a side view.

FIG. 4 is a schematic structural view of a molecular beam epitaxy (MBE) reactor chamber according to an embodiment of the present application.

FIG. 5A to FIG. 5F show schematic structural views of topological insulators respectively having a single (FIG. 5A and FIG. 5D), double (FIG. 5B and FIG. 5E), triple (FIG. 5C and FIG. 5F) magnetically doped topological insulator quantum well films according to embodiments of the present application.

FIG. 6 is a schematic structural view of an electrical device according to an embodiment of the application.

FIG. 7A to FIG. 7F show surface morphologies and reflection high-energy electron diffraction (RHEED) patterns of the multi-channel topological insulators with different layer numbers according to embodiments of the present application, wherein FIG. 7A shows a surface morphology of a topological insulator being a single magnetically doped topological insulator quantum well film, FIG. 7B shows a surface morphology of a topological insulator having a magnetically doped topological insulator quantum well film covered with a CdSe layer having a thickness of 1 nm, and FIG. 7C shows a surface morphology of a topological insulator having double magnetically doped topological insulator quantum well films sandwiching a CdSe layer; FIG. 7D, FIG. 7E, and FIG. 7F show the corresponding RHEED patterns of FIG. 7A, FIG. 7B, and FIG. 7C respectively.

FIG. 8A and FIG. 8B shows transmission electron microscope (TEM) images of a multi-channel topological insulator according to an embodiment of the present application, wherein FIG. 8A corresponds to a superlattice structure formed by four magnetically doped topological insulator quantum well films and three CdSe interlayers, FIG. 8B is a local enlarged view of FIG. 8A.

FIG. 9 is a graph showing an X-ray diffraction (XRD) pattern of a multi-channel topological insulator structure according to an embodiment of the present application.

FIG. 10A to FIG. 10C are graphs showing Hall curves of the topological insulators of FIG. 5A to FIG. 5F of embodiments of the present application under different back gate voltages, wherein FIG. 10A corresponds to the topological insulator having the single magnetically doped topological insulator quantum well film, FIG. 10B corresponds to the topological insulator having the double magnetically doped topological insulator quantum well films, the films having the same coercive field, FIG. 10C corresponds to the topological insulator having the triple magnetically doped topological insulator quantum well films, the films having the same coercive field.

FIG. 11A to FIG. 11C are graphs showing magnetoresistance curves of the topological insulators of FIG. 5 to FIG. 5F of embodiments of the present application under different back gate voltages, wherein FIG. 10A corresponds to the single magnetically doped topological insulator quantum well film, FIG. 10B corresponds to the double magnetically doped topological insulator quantum well films having the same coercive field, FIG. 10C corresponds to the triple magnetically doped topological insulator quantum well films having the same coercive field.

FIG. 12A and FIG. 12B show Hall resistance curves (FIG. 12A) and Hall conductance curves (FIG. 12B) of a double-channel topological insulator with different coercive fields under different back gate voltages according to an embodiment of the present application.

FIG. 13A to FIG. 13H show angle resolved photoemission spectroscopy and second-order differential graphs of topological insulators covered with CdSe having different thicknesses according to an embodiment of the present application, wherein FIG. 13A is the angle resolved photoemission spectroscopy of a magnetically doped topological insulator quantum well film with a thickness of 6 QL without CdSe cover, FIG. 13B corresponds to the film covered with CdSe having a thickness of 0.5 nm, FIG. 13C corresponds to the film covered with CdSe having a thickness of 1 nm, FIG. 13D corresponds to the film covered with CdSe having a thickness of 1.5 nm; and FIG. 13E, FIG. 13F, FIG. 13G, and FIG. 13H are the respective second-order differential graphs of FIG. 13A, FIG. 13B, FIG. 13C, and FIG. 13D.

### DETAILED DESCRIPTION

Detailed description for the double-channel topological insulator structure and the method for generating quantized anomalous Hall Effect will be given below with reference to the accompanying figures and exemplary examples to facilitate illustration and comprehension of the present disclosure. It should be understood that the exemplary examples are merely for the purpose of better understanding of the present disclosure, but not meant to limit the scope thereof.

The terms such as “vertical”, “horizontal”, “left”, “right” and the like used herein are for illustrative purposes. Various objects in the drawings of the embodiments are drawn on a scale that is convenient for description, rather than drawn on the scale of actual components.

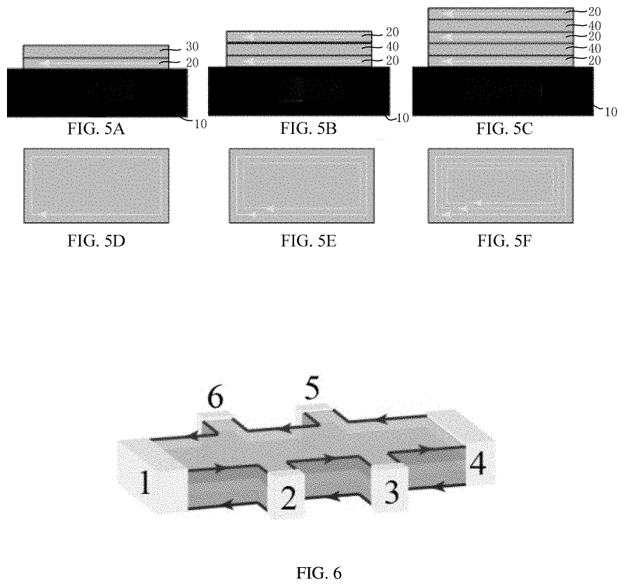

Referring to FIG. 5A and FIG. 5D, an embodiment of the present application first provides a topological insulator structure having an insulating protective layer. The topological insulator structure includes an insulating substrate 10, a topological insulator quantum well film 20, and an insulating protective layer 30. The insulating protective layer 30 and the topological insulator quantum well film 20 have a lattice match with each other. The topological insulator quantum well film 20 and the insulating protective layer 30 are sequentially layered on a surface of the insulating substrate 10 to form a heterojunction structure between the topological insulator quantum well film 20 and the insulating protective layer 30.

The insulating protective layer 30 and the topological insulator quantum well film 20 have similar crystal structures and similar distances between atoms to have a lattice match therebetween, so that the heterojunction structure can be formed to protect the topological insulator quantum well film 20 from being damaged, thereby improving the quality of the topological insulator structure.

In an embodiment, the topological insulator quantum well film 20 is grown on the insulating substrate 10 by the molecular beam epitaxy (MBE).

The molecular beam epitaxy is a film evaporation-deposition method performed at a low deposition rate of 0.1 nm/s to 1 nm/s in an ultra-high vacuum having the order of magnitude corresponding to 10⁻¹⁰ mbar. In an embodiment, after the topological insulator quantum well film 20 is formed, the insulating protective layer 30 is subsequently grown on the surface of the topological insulator quantum well film 20 by the molecular beam epitaxy. The topological insulator quantum well film 20 and the insulating protective layer 30 continuously grown by the molecular beam epitaxy, forming a well-organized heterojunction structure.

The film of the topological insulator is generally grown at a relatively low temperature, and would have desorption of Te if heated for a long time in a vacuum, causing the charge of the film to deviate from the original charge neutral point. Moreover, the over-high temperature would easily cause a decomposition of the film, which damages the film. In an embodiment, the molecular beam epitaxy growth temperature of the insulating protective layer 30 is close to the molecular beam epitaxy growth temperature of the topological insulator quantum well film 20. In an embodiment, the molecular beam epitaxy growth temperature of the insulating protective layer 30 is within a range from the molecular beam epitaxy growth temperature of the topological insulator quantum well film 20 minus 100° C. to that plus 100° C. (MBE growth temperature ±100° C.), so that the growth of the insulating protective layer 30 will not damage the structure of the formed topological insulator quantum well film 20, and that the quantum effect and performance of the topological insulator quantum well film 20 will not be affected by the formation of the insulating protective layer 30.

In the heterojunction structure, the lattice constants of the topological insulator quantum well film 20 and the insulating protective layer 30 approximate to each other, which can reduce the lattice mismatch degree and achieve good lattice match therebetween. In an embodiment, the topological insulator quantum well film 20 has a first lattice constant; the insulating protective layer 30 has a second lattice constant; and a ratio of the first lattice constant to the second lattice constant is between 1:1.1 and 1.1:1. In an embodiment, the topological insulator quantum well film 20 has a hexagonal close-packed crystal plane with a first lattice constant in the hexagonal close-packed crystal plane; the insulating protective layer 30 has a hexagonal close-packed crystal plane with a second lattice constant in the hexagonal close-packed crystal plane; and a ratio of the first lattice constant to the second lattice constant is between 1:1.1 and 1.1:1.

In an embodiment, the topological insulator quantum well film 20 is a magnetically doped topological insulator quantum well film 20 formed by doping a first element and a second element at the Sb site of Sb₂Te₃. The first element is an element to introduce magnetism. The second element is an element to introduce electrons into the topological insulator quantum well film 20, so that the holes and electrons introduced into the topological insulator quantum well film 20 are balanced with each other. By doing so, a carrier density of the magnetically doped topological insulator quantum well film 20 has already dropped to 1×10¹³cm⁻² or less when the magnetically doped topological insulator quantum well film 20 is not regulated by applying voltage to the top gate or the back gate, which ensures the effectiveness of the regulation through the top gate or the back gate when the quantum anomalous Hall effect is achieved by a device having the topological insulator structure. The topological insulator quantum well film 20 can be a quaternary (containing four elements) or a quinary (containing five elements) material. In an embodiment, the first element is one or more selected from Cr, Ti, Fe, Mn, and V, and the second element is Bi. In an embodiment, the material of the topological insulator quantum well film 20 is represented by the chemical formula M_{y}N_{z}(BiₓSb₁₋ₓ)_{2-y-z}Te₃, wherein 0<x<1, 0≤y, 0≤z, and 0<y+z<2. M and N are Cr, Ti, Fe, Mn or V, respectively. M and N can be the same or different elements. In an embodiment, M is Cr and N is V.

In an embodiment, the thickness of the topological insulator quantum well film 20 is in a range from 5 QL to 10 QL, wherein each QL consists of five adjacent atom layers. In an embodiment, the thickness of the insulating protective layer 30 is greater than 0.35 nm, and can be grown to an infinite thickness.

The material of the insulating protective layer 30 can have a hexagonal close-packed (hcp) crystal plane, so as to form a hexagonal close packing in the stacking direction when it is stacked with the doped Sb₂Te₃ topological insulator quantum well film 20. In an embodiment, the material of the insulating protective layer 30 has the wurtzite structure or the sphalerite structure, and the (001) plane of the wurtzite structure or the (111) plane of the sphalerite structure is the hexagonal close-packed crystal plane. In an embodiment, the insulating protective layer 30 is at least one selected from the wurtzite-structured CdSe, the sphalerite-structured ZnTe, the sphalerite-structured CdSe, the sphalerite-structured CdTe, the sphalerite-structured HgSe, and the sphalerite-structured HgTe.

The insulating protective layer 30 and the magnetically doped Sb₂Te₃topological insulator quantum well film 20 have similar epitaxial growth temperatures. The insulating protective layer 30 is capable of being epitaxially grown on the surface of the topological insulator quantum well film 20. The insulating protective layer 30 and the topological insulator quantum well film 20 have similar lattice constants, and lattices thereof are matched with each other, thereby forming a heterojunction structure. In an embodiment, the lattice constant of the magnetically doped topological insulator quantum well film 20 is between the lattice constant of Sb₂Te₃ (0.426 nm in the (001) plane) and the lattice constant of Bi₂Te₃ (0.443 nm in the (001) plane). With the gradual doping of Bi, the lattice constant gradually becomes approximate 0.443 nm rather than approximate 0.426 nm. As for the materials for the insulating protective layer 30, the in-plane lattice constant of the (111) plane of the sphalerite-structured CdTe is 0.457 nm, that of the sphalerite-structured HgSe is 0.424 nm, that of the sphalerite-structured HgTe is 0.456 nm, that of the sphalerite-structured ZnTe is 0.431 nm, and that of the sphalerite-structured CdSe is 0.430 nm. These materials with matched lattices are optional materials for the insulating protective layer 30. In an embodiment, the in-plane lattice constant of the (001) plane of the wurtzite-structured CdSe is 0.430 nm, which is perfectly matched with the lattice constant of the magnetically doped topological insulator (about 3% lattice mismatch degree with Bi₂Te₃, and about 1% lattice mismatch degree with Sb₂Te₃), so that the wurtzite-structured CdSe can be an option for the material of the insulating protective layer 30.

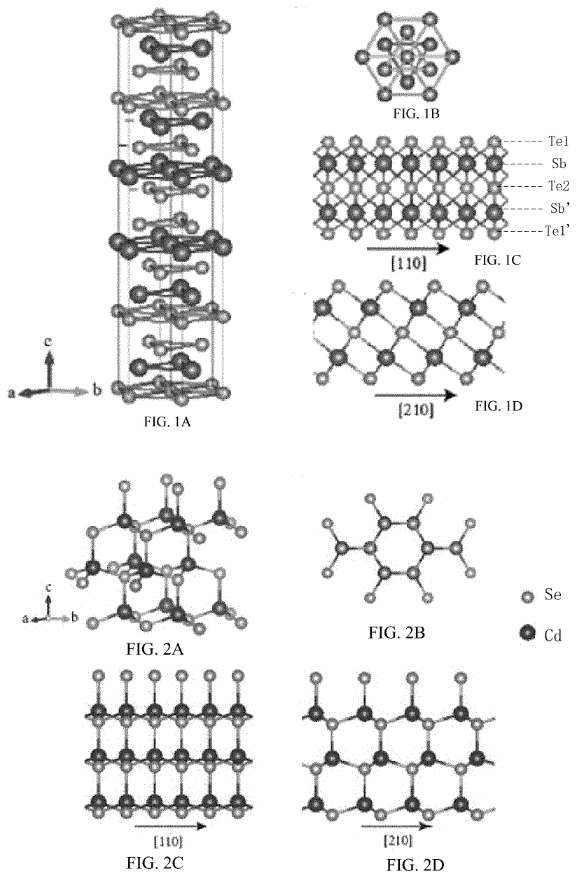

Sb₂Te₃ is a layered material, which belongs to the trigonal crystal system, and belongs to the space group of D_{3d}⁵(R3̅m), and the specific lattice structure is referred to FIG. 1A to FIG. 1D. As shown in FIG. 1A to FIG. 1D, in the ab plane, Sb atoms and Te atoms are respectively arranged in the hexagonal close packing style to form Sb atom layers and Te atom layers. That is, the planes perpendicular to the c-axis are the hexagonal close-packed crystal planes. Sb atom layers and Te atom layers are alternately layered in the direction of the c-axis perpendicular to the ab plane. Each quintuple layer (QL) consists of five adjacent atom layers. In an embodiment, the topological insulator quantum well film 20 is the magnetically doped topological insulator quantum well film 20, and the five adjacent atom layers are respectively the orderly layered first Te atom layer (Te1), the first magnetically doped Sb atom layer (Sb1), the second Te atom layer (Te2), the second magnetically doped Sb atom layer (Sb′), and the third Te atom layer (Te1′). In a single QL, the atoms are joined by covalent-ionic bonds. Between adjacent QLs, the atom layer Te1 and the atom layer Te1′ are combined by van der Waals forces, thus forming cleavage planes between adjacent QLs.

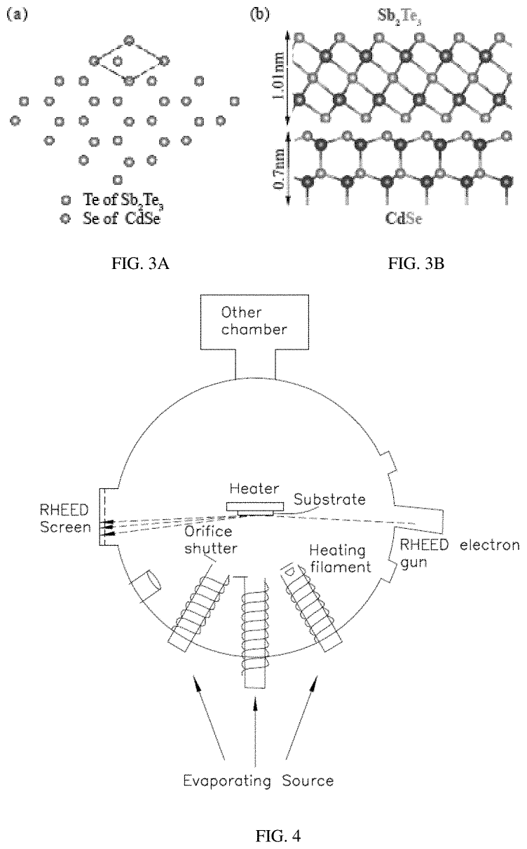

The wurtzite-structured cadmium selenide (CdSe) belongs to the hexagonal crystal system. Referring to FIG. 2A to FIG. 2D for the specific lattice structure, the wurtzite-structured CdSe is formed by alternately stacking Cd and Se in the [001] direction (i.e., the c-axis), and the (001) plane thereof is the hexagonal close-packed plane. FIG. 3A and FIG. 3B show the lattice match between the CdSe insulating protective layer 30 and the magnetically doped topological insulator quantum well film 20. Te in Sb₂Te₃ and Se in CdSe each form a hexagonal structure, and the lattice constants of the two hexagonal structures approximate to each other, which enables the hexagonal close packing to be formed, thereby forming epitaxial structures with the matched lattices, and further forming the heterojunction structure.

Moreover, the molecular beam epitaxy growth temperature of the CdSe film approximates to the molecular beam epitaxy growth temperature of the magnetically doped Sb₂Te₃ topological insulator quantum well film 20. After the formation of the magnetically doped Sb₂Te₃ topological insulator quantum well film 20, the CdSe film, under the same growth temperature in the molecular beam epitaxy reactor chamber, can continue to be grown into the insulating protective layer 30 of the magnetically doped topological insulator quantum well film 20, so as to maximally protect the topological insulator quantum well film 20 from being polluted by the environment, thus improving the quality and performance of the product.

The material of the insulating substrate 10 can be conventional, such as indium phosphide, gallium arsenide, strontium titanate, aluminum (III) oxide, or single crystal silicon. In an embodiment, the material of the insulating substrate 10 can have a dielectric constant greater than 5000 at a temperature equal to or less than 10 Kelvin (K), such as strontium titanate (STO). To achieve a relatively large anomalous Hall resistance, or even achieve the quantum anomalous Hall effect (QAHE), a chemical potential of the magnetically doped topological insulator quantum well film 20 needs to be regulated by applying an external voltage. More specifically, the voltage can be applied to the magnetically doped topological insulator quantum well film through a top gate and/or back gate, so that the chemical potential of the magnetically doped topological insulator quantum well film 20 can be regulated by means of the field effect. The insulating substrate 10, having a relatively large dielectric constant at a relatively low temperature, can still have a relatively large capacitance, though the thickness of the insulating substrate is relatively large. Thus, the insulating substrate 10 can directly serve as the dielectric layer between the back gate and the magnetically doped topological insulator quantum well film 20, thereby achieving the back gate voltage regulation at the relatively low temperature, further achieving the chemical potential regulation of the magnetically doped topological insulator quantum well film 20, and finally achieving the QAHE.

When the material of the insulating substrate 10 is STO, the magnetically doped topological insulator quantum well film 20 can be grown on the STO surface in the (111) plane. The thickness of the STO insulating substrate can be in a range from 0.1 millimeters to 1 millimeter. As other substrate materials except STO have relatively small dielectric constants, the back gate cannot be formed at the back of the substrate. In these cases, a top gate formed of aluminum oxide, zirconia, or boron nitride, etc., or ionic liquid can be used to regulate the chemical potential of the magnetically doped topological insulator quantum well film 20 via the electrostatic field.

Referring to FIG. 4, an embodiment of the present application also provides a method for making the topological insulator structure with the insulating protective layer 30, and the method includes:

S100, providing the insulating substrate 10 in a molecular beam epitaxy reactor chamber;

S200, growing the topological insulator quantum well film 20 by molecular beam epitaxy on a surface of the insulating substrate 10 having a first temperature; and

S300, growing an insulating protective layer 30 by molecular beam epitaxy on a surface of the topological insulator quantum well film 20 having a second temperature.

In step S100, the surface of the insulating substrate 10 is smooth at atomic level. In the embodiment that the insulating substrate 10 is STO, specifically, the surface along the (111) crystal plane can be formed by cutting the STO substrate. The STO substrate is heated in deionized water at a temperature below 100° C. (e.g., 70° C.), and burned in an O₂ and Ar atmosphere at a temperature in a range from 800° C. to 1200° C. (e.g., 1000° C.). The heating time in the deionized water can be 1 hour to 2 hours, and the burning time in the O₂ and Ar atmosphere can be 2 hours to 3 hours.

In step S200, the STO substrate is heated while a beam of the material, or separate beams of elements, of the topological insulator quantum well film 20 are generated in the molecular beam epitaxy reactor chamber, thereby forming the topological insulator quantum well film 20 on the surface of the insulating substrate 10. In an embodiment, the material of the topological insulator quantum well film 20 is represented by the chemical formula M_{y}N_{z}(BiₓSb₁₋ₓ)_{2-y-z}Te₃. Solid Bi, Sb, M, N, and Te evaporation sources can be independently arranged in the molecular beam epitaxy reactor chamber. The beams of Bi, Sb, M, N, and Te are heated, thereby forming the magnetically doped topological insulator quantum well film 20 on the STO substrate. Flow rates of the Bi, Sb, M, N, and Te beams can be controlled to control a ratio of Bi, Sb, M, N, and Te, in order to substantially equalize the number of the hole type charge carriers introduced by M and N with the number of the electron type charge carriers introduced by Bi in the magnetically doped topological insulator quantum well film 20. In an embodiment, M is Cr; N is V; the temperatures of the evaporation sources are respectively T_{Te}=258° C., T_{Bi}=491° C., T_{Sb}=358° C., T_{Cr}=941° C., T_{V}=1557° C.; and the first temperature T_{sub} is from 150° C. to 250° C.

In step S300, an evaporation source of the material of the insulating protective layer 30 is further provided in the MBE reactor chamber. A beam of the material of the insulating protective layer 30 can be formed by heating the evaporation source of the material of the insulating protective layer 30. The flow rate of the beam of the material of the insulating protective layer 30 is controlled to grow the insulating protective layer 30 in situ on the topological insulator quantum well film 20, thereby forming the topological insulator structure having the insulating protective layer 30. During the growth of the insulating protective layer 30, the temperature of the surface of the topological insulator quantum well film 20 is the second temperature. In an embodiment, the growth temperature of the insulating protective layer 30 and the growth temperature of the topological insulator quantum well film 20 approximate to each other, so that the epitaxial growth of the insulating protective layer 30 can be right after the epitaxial growth of the topological insulator quantum well film 20, while the topological insulator quantum well film 20 that has been formed is not damaged or its performance is not affected. The second temperature is in a range from 50° C. to 350° C. Optionally, the second temperature is in a range from the first temperature minus 100° C. to the first temperature plus 100° C. (the first temperature ±100° C.). In an embodiment, the second temperature is in a range from 150° C. to 250° C. In an embodiment, the material of the insulating protective layer 30 is the wurtzite-structured CdSe. The evaporation source of the insulating protective layer 30 is a CdSe block, which forms a CdSe molecule beam as the beam of the material of the insulating protective layer 30, when the evaporation source is heated. The beam in the molecular form is easier to control, and it is easier to form the lattice matched heterojunction structure. In step S300, the heating temperature T_{sub} of the insulating substrate 10 is from 150° C. to 250° C., and the temperature of the CdSe evaporation source is T_{CdSe}=520° C.

Referring to FIG. 5C and FIG. 5F, an embodiment of the present application further provides a multi-channel topological insulator structure including an insulating substrate 10, a plurality of topological insulator quantum well films 20, and a plurality of insulating interlayers 40. The plurality of topological insulator quantum well films 20 and the plurality of insulating interlayers 40 are alternately stacked on a surface of the insulating substrate 10. Two adjacent topological insulator quantum well films 20 are separated by one insulating interlayer 40.

The above-described insulating protective layers 30 are lattice-matched with the topological insulator quantum well films 20. So that, the insulating protective layer 30 can serve as the insulating interlayer 40 in this embodiment, and to continue to grow another topological insulator quantum well film 20 thereon, thereby forming the multi-channel topological insulator. The plurality of topological insulator quantum well films 20 can be independently connected to an external circuit, so as to be used as independent electrical components. Multiple topological insulator quantum well films 20 can be connected in parallel by electrodes. The parallel connection can significantly reduce contact resistance between the topological insulator structure as a whole and each of the electrodes, thereby reducing energy consumption.

The insulating interlayer 40 and the topological insulator quantum well film 20 adjacent to each other have lattice-matched structures. The plurality of topological insulator quantum well films 20 are separated by the insulating interlayers 40 to jointly form the multi-channel topological insulator having a superlattice structure.

The thickness of each of the topological insulator quantum well films 20 can be in a range from 5 QL to 10 QL. The thickness of the insulating interlayer 40 can be in a range from 0.35 nm to 20 nm.

In the superlattice structure, the topological insulator quantum well film 20 and the insulating interlayer 40 adjacent to each other have similar lattice constants, which can reduce the lattice mismatch degree and achieve well lattice match therebetween. In an embodiment, a ratio of the lattice constant of the topological insulator quantum well film 20 to the lattice constant of the adjacent insulating interlayer 40 is between 1:1.1 and 1.1:1.

The insulating interlayers 40 are grown on the surfaces of the topological insulator quantum well films 20 by the molecular beam epitaxy. Both the insulating interlayers 40 and the topological insulator quantum well films 20 are formed by the molecular beam epitaxy growth method. The difference between the molecular beam epitaxy growth temperature of any insulating interlayer 40 and the molecular beam epitaxy growth temperature of any topological insulator quantum well film 20 is less than or equal to 100° C. The difference between the molecular beam epitaxy growth temperatures of any two topological insulator quantum well films 20 is less than or equal to 100° C. The difference between the molecular beam epitaxy growth temperatures of any two insulating interlayers 40 is less than or equal to 100° C. So that, the topological insulator quantum well films 20 and the insulating interlayers 40 can continuously, alternately, and epitaxially grown under substantially the same temperature conditions. Moreover, during the formation of the subsequent insulating interlayers 40, the topological insulator quantum well films 20 that have been formed will not be damaged.

The topological insulator quantum well films 20 can be the magnetically doped topological insulator quantum well films 20 formed by magnetic doping. As such, a multi-channel quantum anomalous Hall effect can be achieved under an action of external electric field and magnetic field applied on the magnetically doped topological insulator quantum well films 20. Different magnetically doped topological insulator quantum well films 20 in the multi-channel topological insulator structure can be made of the same or different materials, as long as they can have lattice match with the adjacent insulating interlayers 40 to generate the multi-channel quantum anomalous Hall effect. In an embodiment, the material of each topological insulator quantum well film 20 is represented by the chemical formula M_{y}N_{z}(BiₓSb₁₋ₓ)_{2-y-z}Te₃, wherein 0<x<1, 0≤y, 0≤z, and 0<y+z<2. M or N is a magnetic doping element, selected from Cr, Ti, Fe, Mn or V. M or N can be the same or different elements. In addition, different magnetically doped topological insulator quantum well films 20 can have the same or different M, or have the same or different N; and the corresponding numerical values of x, y, and z can be respectively the same or different. In an embodiment, the materials of all topological insulator quantum well films 20 are the same, so that the multi-channel topological insulator having multiple identical Hall resistances connected in parallel can be formed. In an embodiment, M, N, x, y, and z in the chemical formulae of the materials of all topological insulator quantum well films 20 are respectively identical. When the electric field and the magnetic field are applied, all topological insulator quantum well films 20 generate the same edge state currents, thereby generating the multi-channel quantum anomalous Hall effect.

The insulating protective layer 30 can serve as the insulating interlayer 40. The insulating protective layer 30 can be selected from the wurtzite-structured CdSe, the sphalerite-structured ZnTe, the sphalerite-structured CdSe, the sphalerite-structured CdTe, the sphalerite structured-HgSe, or the sphalerite-structured HgTe. The wurtzite-structured CdSe and the magnetically doped Sb₂Te₃ topological insulator quantum well film 20 have better lattice match and more similar growth temperatures, and the wurtzite-structured CdSe is an option for the insulating interlayer 40.

In an embodiment, the multi-channel topological insulator structure further includes the insulating protective layer 30 that is finally stacked on the topmost topological insulator quantum well film 20 to prevent the topological insulator quantum well film 20 that is finally stacked from being damaged. When the final stacked layer is the insulating interlayer 40, the insulating layer can serve as the insulating protective layer 30. When the final stacked layer is the topological insulator quantum well film 20, the insulating protective layer 30 can be further stacked thereon. The insulating protective layer 30 is at least one selected from the wurtzite-structured CdSe, the sphalerite-structured ZnTe, the sphalerite-structured CdSe, the sphalerite-structured CdTe, the sphalerite-structured HgSe, and the sphalerite-structured HgTe. The materials of the insulating protective layer 30 and the plurality of insulating interlayers 40 can be identical or different, and are identical in an embodiment to simplify the evaporation sources required in the growth.

An embodiment of the present application also provides a method for making the multi-channel topological insulator structure, and the method includes:

S100, providing the insulating substrate 10 in a molecular beam epitaxy reactor chamber; and

S200, alternately growing the plurality of topological insulator quantum well films 20 and the plurality of insulating interlayers 40 on a surface of the insulating substrate 10 by molecular beam epitaxy.

In an embodiment, the molecular beam epitaxy growth temperature of the insulating interlayer 40 approximates to the molecular beam epitaxy growth temperature of any topological insulator quantum well film 20. The topological insulator quantum well films 20 and the insulating protective layers 30 can be continuously, alternately, and epitaxially grown when the temperature conditions are substantially identical. Moreover, during the formation of the subsequent insulating interlayers 40, the topological insulator quantum well films 20 that have been formed are not damaged. In an embodiment, the growth temperatures of the topological insulator quantum well films 20 are all in a range from 150° C. to 250° C., and the growth temperatures of the insulating interlayers 40 are all in a range from 50° C. to 350° C. In an embodiment, the growth temperatures of the plurality of topological insulator quantum well films 20 and the plurality of insulating interlayers 40 are all in a range from 150° C. to 250° C.

Referring to FIG. 6, an embodiment of the present application further provides an electrical device including the multi-channel topological insulator structure. The topological insulator quantum well film 20 of the multi-channel topological insulator structure is a magnetically doped topological insulator quantum well film 20. Further, the electrical device includes a gate (e.g., a back gate or a top gate) and two conducting electrodes 1 and 4 (that is, a source electrode and a drain electrode). The gate is configured to regulate the chemical potential of the magnetically doped topological insulator quantum well film 20. The two conducting electrodes 1, 4 are spaced and are respectively and electrically connected to the topological insulator quantum well film 20. A direction from one conducting electrode 1 to the other conducting electrode 4 is a first direction (i.e., the longitudinal resistance direction), and a direction perpendicular to the first direction is a second direction. The two conducting electrodes 1, 4 are respectively disposed at two ends of the multi-channel topological insulator in the first direction, and are configured to conduct an electric current in the first direction through the multi-channel topological insulator structure. In an embodiment, each conducting electrode 1 or 4 is electrically connected to all topological insulator quantum well films 20, so as to connect the plurality of topological insulator quantum well films 20 in parallel. The two conducting electrodes 1, 4 can be strip-shaped and have a relatively long length, and the length directions of the two conducting electrodes are arranged in the second direction. The lengths of the conducting electrodes 1 and 4 can be equal to the length of the multi-channel topological insulator structure in the second direction.

The electrical device can further include three output electrodes (respectively 2, 3, and 5). The three output electrodes 2, 3, and 5 are spaced apart from each other, and are electrically and respectively connected to the topological insulator quantum well film 20, in order to output the resistance of the multi-channel topological insulator structure in the first direction (i.e., the longitudinal resistance) and output the resistance in the second direction (i.e., the Hall resistance). A direction from the output electrode 2 to the output electrode 3 is the first direction (i.e., the longitudinal resistance direction), and a direction from the output electrode 3 to the output electrode 5 is the second direction (i.e., the Hall resistance direction). The output electrodes 2, 3, and 5 can be respectively disposed at two ends of the multi-channel topological insulator opposite in the second direction; for example, the output electrodes 2 and 3 are disposed at the same end of the multi-channel topological insulator in the second direction, and the output electrode 5 is disposed at the other end of the multi-channel topological insulator in the second direction. All three output electrodes can be dot-shaped electrodes. In an embodiment, each output electrode is electrically and respectively connected to all topological insulator quantum well films 20, so as to connect the plurality of topological insulator quantum well films 20 in parallel. The longitudinal resistance and the Hall resistance are both resistances formed by the plurality of magnetically doped topological insulator quantum well films 20 connected in parallel.

In an embodiment, the insulating substrate 10 has a first surface and a second surface opposite to each other. The plurality of magnetically doped topological insulator quantum well films 20 and the plurality of insulating interlayers 40 are disposed on the first surface. The back gate is disposed on the second surface. The two conducting electrodes and four output electrodes can be spaced apart from each other and disposed on the surface of the multi-channel topological insulator, so as to be electrically connected to the multi-channel topological insulator. All the above-mentioned electrodes can be formed by the electron beam evaporation (E-beam) method, and the materials thereof can be gold or titanium with better conductivity. Otherwise, an indium paste or a silver paste can be directly applied on the surface of the sample to serve as an electrode.

In addition, the electrical device can further include a fourth output electrode 6 similar to the output electrodes 2, 3, and 5. The output electrode 6 and the output electrodes 2, 3, and 5 are spaced apart from each other, and are respectively disposed on the two ends of the multi-channel topological insulator structure opposite with each other in the second direction. For example, the output electrodes 2 and 3 are disposed on one end of the multi-channel topological insulator in the second direction, and the output electrodes 5 and 6 are disposed on the other end of the multi-channel topological insulator in the second direction.

The plurality of magnetically doped topological insulator quantum well films 20 are connected in parallel to form Hall resistances connected in parallel and longitudinal resistances connected in parallel. Although the topological insulator has a dissipationless edge state, the current ends will be hot spots, and the hot spots will have heat dissipation. The multi-channel quantum anomalous Hall effect formed by the multi-channel topological insulator structure can reduce the contact resistance between the conducting electrodes at the current ends and the magnetically doped topological insulator quantum well film 20 via the parallel connection, thereby reducing energy dissipation.

In addition, the superlattice structure formed in the multi-channel topological insulator is likely to realize the Weyl semimetal state. The coupling strength between the top and bottom surfaces of the magnetically doped topological insulator quantum well film 20 can be varied by regulating the thickness of the magnetically doped topological insulator quantum well film 20, while the magnitude of the magnetic exchange interaction can be varied by regulating the magnetic doping amount in each layer. In addition, the coupling strength between the surfaces of the adjacent magnetically doped topological insulator quantum well films 20 can be varied by regulating the thickness of the insulating interlayer 40. The Weyl semimetal state can be realized when these three values of the multi-channel topological insulator are regulated to satisfy certain conditions. This is a potential application of the superlattice structure of the multi-channel topological insulator.

Based on the multi-channel topological insulator structure, referring to FIG. 5B and FIG. 5E, an embodiment of the present application further provides a double-channel topological insulator structure which includes an insulating substrate 10, two topological insulator quantum well films 20 (i.e., a first topological insulator quantum well film and a second topological insulator quantum well film), and an insulating interlayer 40. The first topological insulator quantum well film, the insulating interlayer 40, and the second topological insulator quantum well film are sequentially stacked on the insulating substrate 10. The first topological insulator quantum well film and the second topological insulator quantum well film are spaced by the insulating interlayer 40.

The first topological insulator quantum well film, the insulating interlayer 40 and the second topological insulator quantum well film are lattice-matched with each other, and are sequentially stacked on the surface of the insulating substrate 10 to cooperatively form a heterojunction structure. The first topological insulator quantum well film has a first lattice constant. The insulating interlayer 40 has a second lattice constant. The second topological insulator quantum well film has a third lattice constant. The ratio of the first lattice constant to the second lattice constant is between 1:1.1 and 1.1:1. The ratio of the second lattice constant to the third lattice constant is between 1:1.1 and 1.1:1.

The insulating interlayer 40 is grown on the surface of the first topological insulator quantum well film 20 by the molecular beam epitaxy. In an embodiment, the molecular beam epitaxy growth temperature of the insulating interlayer 40 is in a range from the molecular beam epitaxy growth temperature of the first topological insulator quantum well film minus 100° C. to the molecular beam epitaxy growth temperature of the first topological insulator quantum well film plus 100° C. (growth temperature ±100° C.); and the molecular beam epitaxy growth temperature of the second topological insulator quantum well film is in a range from the molecular beam epitaxy growth temperature of the insulating interlayer minus 100° C. to the molecular beam epitaxy growth temperature of the insulating interlayer 40 plus 100° C. (growth temperature±100° C.).

The materials of the first topological insulator quantum well film 20 and the second topological insulator quantum well film 20 can be identical or different. The magnetically doped topological insulator quantum well film 20 has a coercive field. The coercive field refers to a required magnetic field applied to a material to reduce the spontaneous magnetization of the material to zero.

Different magnetically doped topological insulators have different coercive fields. Different topological insulators with different coercive fields can be obtained by doping different amounts of or different types of magnetic elements. The first topological insulator quantum well film has a first coercive field (Hc1), and the second topological insulator quantum well film has a second coercive field (Hc2). When the magnetic doping materials of the first and second topological insulator quantum well films are identical, the first coercive field is equal to the second coercive field, and the first and second magnetically doped topological insulator quantum well films have the same chiral edge state (both clockwise or both counterclockwise) when they are in an arbitrary magnetic field (H). When the types and/or ratios of magnetic doping materials of the first and second topological insulator quantum well films are different, the first coercive field is larger or smaller than the second coercive field. When the value of the applied magnetic field (H) is between the first coercive field (Hc1) and the second coercive field (Hc2) (i.e., Hc1<H<Hc2), the currents generated thereby in the first and second topological insulator quantum well films of the double-channel topological insulator can have opposite chiral edge states, and respectively are a clockwise and a counterclockwise spiral edge state currents, thereby realizing the quantum spin Hall effect (QSHE).

In an embodiment, by regulating the amounts of the magnetic doping elements, the materials of the first and second topological insulator quantum well films have different magnetic doping, so that the first coercive field is larger or smaller than the second coercive field. The material of the first topological insulator quantum well film is represented by the chemical formula M_{y}N_{z}(BiₓSb₁₋ₓ)_{2-y-z}Te₃, and the material of the second topological insulator quantum well film 20 is represented by the chemical formula M′_{y′}N′_{z′}(Bi_{x′}Sb_{1-x′})_{2-y′-z′}Te₃, wherein M, M′, N, N′ are independently selected from one of Cr, Ti, Fe, Mn and V; 0<x<1, 0≤y, 0≤z, and 0<y+z<2; 0<x′<1, 0≤y′, 0≤z′ and 0<y′+z′<2; x≠x′ and/or y≠y′ and/or z≠z′.

In another embodiment, by regulating the types of the magnetic doping elements, the materials of the first and second topological insulator quantum well films 20 have different magnetic doping, so that the first coercive field is larger or smaller than the second coercive field. The material of the first topological insulator quantum well film is represented by the chemical formula M_{y}N_{z}(BiₓSb₁₋ₓ)_{2-y-z}Te₃, and the material of the second topological insulator quantum well film is represented by the chemical formula M′_{y′}N′_{z′}(Bi_{x′}Sb_{1-x′})_{2-y′-z′}Te₃, where M, M′, N, N′ are independently selected from one of Cr, Ti, Fe, Mn, and V, and M≠M′, and/or N≠N′; 0<x<1, 0≤y, 0≤z, and 0<y+z<2; 0<x′<1, 0≤y′, 0≤z′ and 0<y′+z′<2.

The lattices of the insulating interlayer 40 and the lattices of the first and second topological insulator quantum well films are matched with each other. In an embodiment, the material of the topological insulator quantum well film 20 is the magnetically doped Sb₂Te₃, and the material of the insulating interlayer 40 is at least one selected from the wurtzite-structured CdSe, the sphalerite-structured ZnTe, the sphalerite-structured CdSe, the sphalerite-structured CdTe, the sphalerite-structured HgSe, and the sphalerite-structured HgTe.

In an embodiment, the double-channel topological insulator structure further includes the insulating protective layer 30 that is stacked on the second topological insulator quantum well film. The insulating protective layer 30 is subsequently grown on the surface of the second topological insulator quantum well film, thus protecting the second topological insulator quantum well film 20 from being damaged. In an embodiment, an additional insulating interlayer 40 can be stacked on the second topological insulator quantum well film to serve as the insulating protective layer 30, the material of which is at least one selected from the wurtzite-structured CdSe, the sphalerite-structured ZnTe, the sphalerite-structured CdSe, the sphalerite-structured CdTe, the sphalerite-structured HgSe, and the sphalerite-structured HgTe.

An embodiment of the present application also provides a method for making the double-channel topological insulator structure, and the method includes:

S100, providing the insulating substrate 10 in a molecular beam epitaxy reactor chamber;

S200, growing the first topological insulator quantum well film by molecular beam epitaxy on the surface of the insulating substrate 10 having the first temperature;

S300, growing the insulating interlayer 40 by molecular beam epitaxy on the surface of the first topological insulator quantum well film having the second temperature; and

S400, growing the second topological insulator quantum well film by molecular beam epitaxy on the surface of the insulating interlayer 40 having a third temperature.

The second temperature is in a range from the first temperature minus 100° C. to the first temperature plus 100° C. (first temperature ±100° C.). The third temperature is in a range from the first temperature minus 100° C. to the first temperature plus 100° C. (first temperature ±100° C.). The first topological insulator quantum well film, the insulating protective layer 30, and the second topological insulator quantum well film can be continuously, alternately, and epitaxially grown under substantially the same temperature conditions. Moreover, during the formation of the subsequent insulating interlayer 40, the first topological insulator quantum well film that has been formed will not be damaged. In an embodiment, the first temperature is in a range from 150° C. to 250° C.; the second temperature is in a range from 50° C. to 350° C.; and the third temperature is in a range from 150° C. to 250° C. In an embodiment, the first temperature, the second temperature, and the third temperature are all in a range from 150° C. to 250° C.

In steps S200 and S400, by regulating the types or doping amounts of the magnetic doping elements in the first and second topological insulator quantum well films, the first and second topological insulator quantum well films can have different coercive fields. In an embodiment, the material of the first topological insulator quantum well film is represented by the chemical formula Cr_{y}V_{z}(BiₓSb₁₋ₓ)_{2-y-z}Te₃, and the material of the second topological insulator quantum well film is represented by the chemical formula Cr_{y}V_{z}(BiₓSb₁₋ₓ)_{2-y′-z′}Te₃. In an embodiment, 0.05<x<0.5, 0<y<0.3, 0<z<0.3, and 0.05<x′<0.5, 0<y′<0.3, 0<z′<0.3. By regulating the ratios of x, y and z, and the ratios of x′, y′ and z′, different magnetic doping of the first and second topological insulator quantum well films are realized.

An embodiment of the present application also provides a method for generating quantum spin Hall effect (QSHE), and the method includes:

providing the double-channel topological insulator, the first topological insulator quantum well film having a first coercive field, and the second topological insulator quantum well film having a second coercive field, the first coercive field being greater or smaller than the second coercive field; and

applying a magnetic field which is ranged between the first coercive field and the second coercive field to the double-channel topological insulator.

Since the first and second topological insulator quantum well films of the double-channel topological insulator have different magnetic doping and have unequal coercive fields, the first and second topological insulator quantum well films will generate opposite edge state currents when the value of the applied magnetic field is between the value of the first coercive field and the value of the second coercive field, thereby realizing the quantum spin Hall effect.

### EXPERIMENTS

Different embodiments of the electrical devices are formed by employing different magnetically doped topological insulator quantum well films 20. A constant electric current is conducted through the magnetically doped topological insulator quantum well film 20 by the two conducting electrodes at a low temperature. Resistances Rₓₓ and R_{yx} in different directions of the magnetically doped topological insulator quantum well film 20 are measured by using the three output electrodes, wherein Rₓₓ is the resistance in the direction of the constant electric current (i.e., the first direction), and R_{yx} is the resistance in the direction perpendicular to the constant electric current (i.e., the second direction), that is, the R_{yx} is the Hall resistance. In the experiment, the chemical potential of the magnetically doped topological insulator quantum well film 20 is regulated by regulating a top gate voltage or a back gate voltage as required. The top gate voltage is represented by Vₜ, and the back gate voltage is represented by V_{b}. Moreover, the magnetic properties of the magnetically doped topological insulator quantum well films 20 are analyzed via a low-temperature and high-intensity-magnetic-field transport measurement system. The experiment results are described in the following embodiments.

In the magnetic materials, it is defined that R_{yx}=R_{A}M(T,H)+R_{N}H, wherein R_{A} is the anomalous Hall coefficient; M(T,H) is the magnetization; and R_{N} is the normal Hall coefficient. The value of the anomalous Hall resistance (R_{AH}) is defined as the value of the Hall resistance in zero magnetic field, namely, R_{AH}=R_{A}M(T,H=0). The R_{A}M(T,H) is the anomalous Hall resistance, which is related to the magnetization (i.e., M(T,H)), and plays the major part of R_{yx} in a low magnetic field. The R_{N}H is the normal Hall resistance, which is the linear part of R_{yx} at a high intensity magnetic field. R_{N} decides the carrier density (n_{2D}), and the type of the charge carriers. The following experiments are processed at a temperature lower than the ferromagnetic transition temperature. The carrier density in the system is relatively low, so that R_{yx} in the zero magnetic field can be regarded to be approximately equal to R_{AH}. The longitudinal resistivity ρₓₓ and the Hall resistivity ρ_{yx} are conversely calculated.

### Embodiment 1

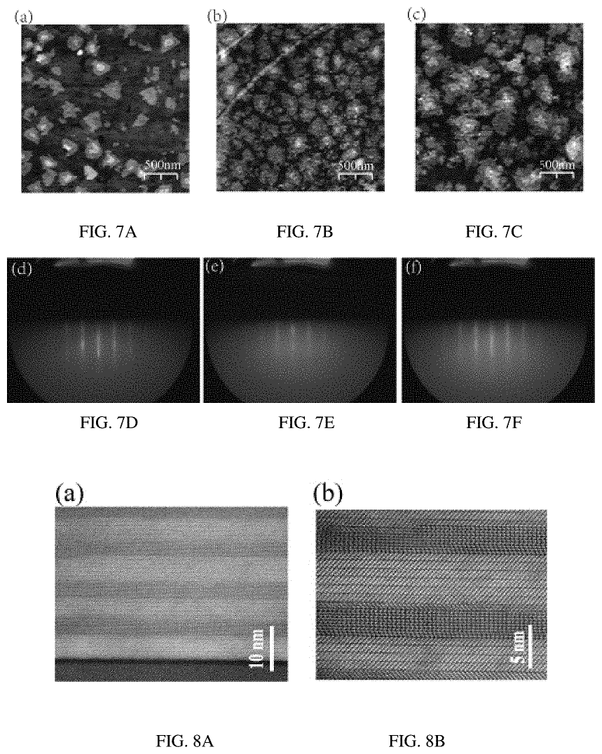

The surface morphology and RHEED stripes of the grown samples are analyzed. FIG. 7A to FIG. 7C show respectively surface morphologies of a single magnetically doped topological insulator quantum well film 20, a magnetically doped topological insulator quantum well film 20 covered with a CdSe insulating protective layer 30 having a thickness of about 1 nm, and double magnetically doped topological insulator quantum well films 20 sandwiching a CdSe insulating interlayer 40 having a thickness of 1 nm. FIG. 7D to FIG. 7F respectively show their corresponding RHEED patterns.

The comparison between FIG. 7A and FIG. 7B shows that after the CdSe is grown on the magnetically doped topological insulator quantum well film 20, the surface morphology of the sample substantially has no change. From the comparison of the RHEED patterns between FIG. 7D and FIG. 7E, it can be seen that, after the CdSe has been grown, the in-plane lattice constant of the sample substantially has no change either, which indicates that the layers have a good lattice match. From FIG. 7C and FIG. 7F, it can be seen that the quantum anomalous Hall effect film can be further grown on the CdSe, and the surface morphology shows no obvious change either. The islands on the quantum anomalous Hall effect film can still be seen. The RHEED patterns also indicate that a high-quality magnetically doped topological insulator quantum well film 20 can be grown on the CdSe.

### Embodiment 2

The lattice structure of the topological insulator having the CdSe insulating protective layer 30 is analyzed by TEM. Referring to FIG. 8A and FIG. 8B, FIG. 8A corresponds to the superlattice structure formed by stacking four magnetically doped topological insulator quantum well films 20 each with a thickness of about 6 QL and three CdSe protective layers each with a thickness of about 3.5 nm, FIG. 8B is an enlarged local area thereof. It can be seen that the magnetically doped topological insulator quantum well film 20 and the CdSe protective layer have a very good lattice match for the epitaxial growth, thereby forming the superlattice structure. The magnetically doped topological insulator quantum well film 20 with a thickness of 6 QL can be well sandwiched between the CdSe insulating protective layers 30 to form a capsule structure, which can take an excellent protective effect on the topological insulator.

### Embodiment 3

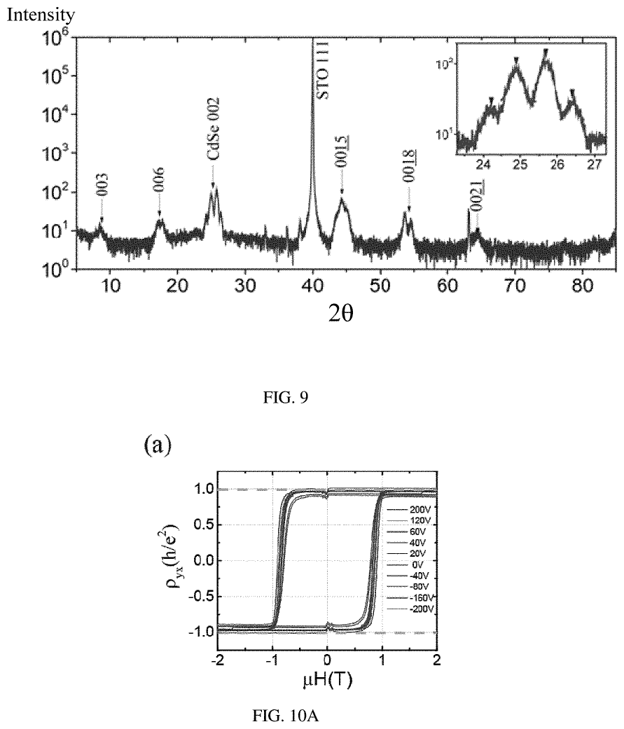

The topological insulator having the CdSe insulating protective layer 30 is analyzed by XRD. Refer to FIG. 9, in which 003, 006, 0015, 0018, and 0021 denote XRD peaks of the magnetically doped topological insulator quantum well film 20. Where 002 denotes a characteristic peak of the CdSe, and 111 denotes a characteristic peak of the strontium titanate (STO) substrate. At the peak 002 of the CdSe and the peak 0018 of the magnetically doped topological insulator quantum well film 20, satellite peaks of the superlattice structure can be seen clearly. The graph at the upper right corner is an enlarged local area of the satellite peaks.

The XRD results indicate that the grown multi-channel topological insulator is of high quality, and has a strict periodicity in the growth direction of the superlattice. From the satellite peaks of the superlattice, the period d of the superlattice can be calculated as the sum of the thickness d1 of the magnetically doped topological insulator quantum well film 20 and the thickness d2 of the CdSe, that is d=d1+d2, and no impurity phase is observed in a large range.

### Embodiment 4

In this embodiment, each of the magnetically doped topological insulator quantum well films 20 is Cr_{0.2}V_{0.16}(Bi_{0.34}Sb_{0.66})_{1.82}Te₃ with a thickness of 6 QL. Each of the insulating substrates 10 is the STO substrate. The thickness of each CdSe layer is 3.5 nm.

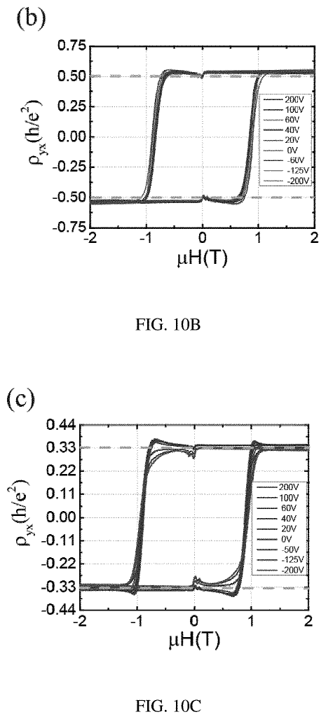

Referring to FIGS. 10A to 10C, the Hall curves of the topological insulators are analyzed at different back gate voltages. The topological insulators respectively include one (shown in a), two (shown in b), and three (shown in c) magnetically doped topological insulator quantum well films 20. The films 20 are identical so as to have the same coercive fields.

At the temperature of 30 millikelvin (mK), the Hall resistivity ρ_{yx} of the samples changes with the back gate voltage (V_{b}). The Hall curves in FIGS. 10A to 10C exhibit hysteresis phenomena, indicating that the samples have excellent ferromagnetic properties. Where H in μ₀H denotes the magnetization; μ₀ denotes the vacuum permeability; the unit T represents Tesla; and ρ_{yx} denotes the Hall resistivity.

By regulating the gate voltages, the changes in Hall resistances can be observed. The three samples respectively show one Hall platform, ½ of a Hall platform, and ⅓ of a Hall platform, which means that they respectively have one, two, and three electric conducting edge states, and respectively have about one quantum Hall resistance, ½ of a quantum Hall resistance, ⅓ of a quantum Hall resistance. It indicates that the three samples are single-channel, double-channel, and three-channel quantum anomalous Hall effect samples respectively.

### Embodiment 5

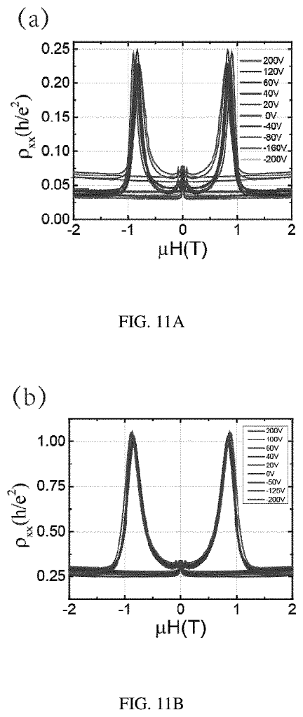

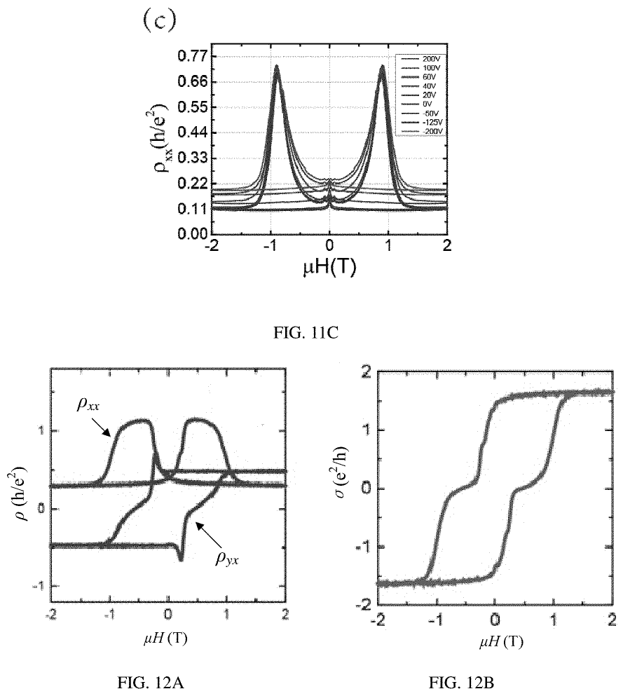

The magnetoresistance curves of the samples of the embodiment 4 are analyzed at different back gate voltages. Referring to FIGS. 11A to 11C, at different back gate voltages V_{b}, all magnetoresistance curves have “butterfly” shapes, which also indicates that the samples have excellent ferromagnetic properties. It can be seen that there are no significant differences between the locations of the magnetoresistance peaks of the single-channel, double-channel and three-channel quantum anomalous Hall effect samples, which means that the magnetic coercive fields are substantially identical in different films.

### Embodiment 6

In this embodiment, the topological insulator sample have two layers of magnetically doped topological insulator quantum well films 20 sandwiching one CdSe insulating interlayer 40 with a thickness of 3.5 nm. The first magnetically doped topological insulator quantum well film is Cr_{0.02}V_{0.16}(Bi_{0.34}Sb_{0.66})_{1.82}Te₃ with a thickness of 6 QL. The insulating substrate 10 is the STO substrate. The thickness of the CdSe insulating interlayer 40 is 3.5 nm. The second magnetically doped topological insulator quantum well film is Cr_{0.10}V_{0.08}(Bi_{0.44}Sb_{0.56})_{1.82}Te₃ and has a thickness of 6 QL. The first and second magnetically doped topological insulator quantum well films have the first and second coercive fields different from each other.

The Hall curves and the magnetoresistance curve of the sample are analyzed. Referring to FIG. 12A and FIG. 12B, when the back gate voltage V_{b} is −150V and the top gate voltage Vₜ is 5V, and the applied magnetic field is between 0.4 T and 0.6 T, it can be seen that the curve of the Hall conductance σ_{yx} has a platform at zero Hall conductance, which indicates that the Hall conductance σ_{yx} is approximately zero at this platform and is an evidence for the appearance of the spiral edge state. Moreover, in a case that the back gate voltage, the top gate voltage, and the magnetic field range are the same as those above, ρₓₓ also shows a platform at a value close to 1.25 h/e², deviating away from the value 0.5 h/e² measured in the perfect quantum spin Hall effect at the same conditions. However, the ρ_{yx} curve also has a bent section at about zero Hall resistance, which indicates that the Hall voltages in the opposite directions of the upper and lower magnetic topological insulator quantum well films are offset with each other, so that the Hall resistance approximates to zero. That is to say, the two quantum well films regarded as a whole shows no Hall effect, but the spin Hall effect does exist. The spiral edge state exists only because there are some residual resistances in the upper and lower films, which deviate from the quantized value. When the back gate voltage and the top gate voltage are regulated to deviate from V_{b}=−150V and Vₜ=5V, the platforms of the Hall conductance σ_{yx} and the Hall resistance ρₓₓ will deviate from zero, and the platforms becomes inclined. Adjusting the chemical potential can make the system gradually away from the quantum spin Hall effect. When the applied magnetic field is larger than the coercive field of the first film and the second film, the directions of the edge states of the two films become identical, that is, the quantum anomalous Hall effects of two channels are connected in parallel connection, and the Hall resistance ρₓₓ will approximate to a quantized value of 0.5 h/e²; and the Hall conductance will approximate to the quantized value of 2e²/h.

By varying the doping amounts of Cr and V in the first and second magnetic topological insulator quantum well films, the coercive field Hc1 of the first film and the coercive field Hc2 of the second film can be respectively changed. When the value of the applied magnetic field is between Hc1 and Hc2, the quantum spin Hall effect appears. In the above sample, the coercive field of the first film is about 0.8 T, and the coercive field of the second film is about 0.2 T. Ideally, the so-called artificial quantum spin Hall effect will appear at the magnetic field of 0.2 T to 0.8 T. This embodiment realizes an approximate quantum spin Hall effect in the range from 0.4 T to 0.6 T.

### Embodiment 7

In this embodiment, an angle resolved photoemission spectroscopy characterization and a corresponding second-order differential characterization of the topological insulator samples having the CdSe insulating protective layers 30 with different thicknesses. The magnetically doped topological insulator quantum well film is Cr_{0.02}V_{0.16}(Bi_{0.34}Sb_{0.66})_{1.82}Te₃. with a thickness of 6 QL.

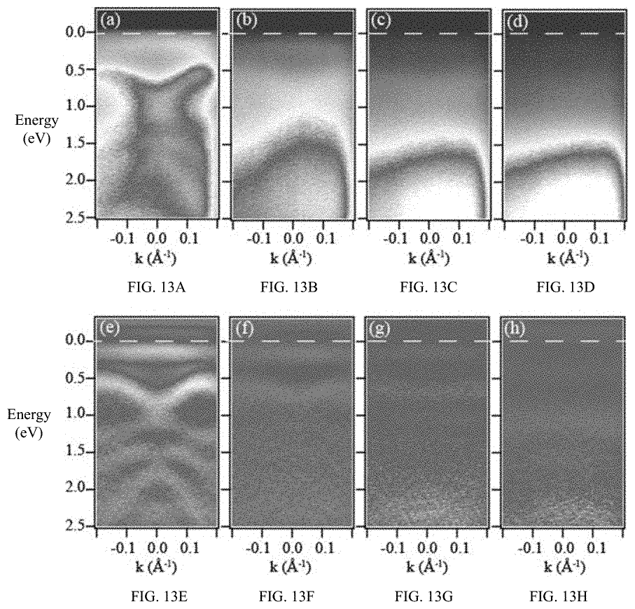

Referring to FIG. 13A to FIG. 13H, wherein the angle resolved photoemission spectroscopies are respectively correspond the topological insulator sample without CdSe (FIG. 13A), the topological insulator sample having CdSe with the thickness of 0.5 nm (FIG. 13B), the topological insulator sample having CdSe with the thickness of 1 nm (FIG. 13C), and the topological insulator sample having CdSe with the thickness of 1.5 nm (FIG. 13D). FIG. 13E, FIG. 13F, FIG. 13G, and FIG. 13H are the respective second-order differential graphs corresponding to the samples of FIG. 13A, FIG. 13B, FIG. 13C, and FIG. 13D.

The growth of the protective layer on the magnetically doped topological insulator quantum well film 20 having the quantum anomalous Hall effect may induce a p-n type change of the magnetically doped topological insulator quantum well film 20. In addition, the poor quality of the sample interface may increase the resistance of the sample. The comparison between FIG. 13A, FIG. 13B and FIG. 13E, FIG. 13F of the embodiments of the present application shows that the covering of the CdSe with the thickness of 0.5 nm does not vary the energy band of the covered magnetically doped topological insulator quantum well film 20. That is, the covering of the CdSe with the thickness of 0.5 nm does not induce a charge transfer or p-n type change in the covered magnetically doped topological insulator quantum well film 20, so that the CdSe cover will not interfere with the anomalous Hall effect, which is important for the protection of quantum anomalous Hall effect. However, the covering of the CdSe with the thickness of 1 nm or 1.5 nm will cause the surface state to be in the energy gap of CdSe.

The technical features of the above-described embodiments may be arbitrarily combined. In order to make the description simple, not all possible combinations of the technical features in the above embodiments are described. However, as long as there is no contradiction in the combination of these technical features, the combinations should be in the scope of the present disclosure.

What described above are only several implementations of the present disclosure, and these embodiments are specific and detailed, but not intended to limit the scope of the present disclosure. It should be understood by the skilled in the art that various modifications and improvements can be made without departing from the conception of the present disclosure, and these modifications and improvements all fall within the protection scope of the present application. Therefore, the patent protection scope of the present disclosure is defined by the appended claims.

What is claimed is:

1. A double-channel topological insulator structure, comprising:
an insulating substrate,
a first topological insulator quantum well film,
an insulating interlayer, and
a second topological insulator quantum well film,
wherein the first topological insulator quantum well film, the insulating interlayer, and the second topological insulator quantum well film are orderly stacked on a surface of the insulating substrate, the first and second topological insulator quantum well films are separated by the insulating interlayer.

2. The double-channel topological insulator structure of claim 1, wherein the first topological insulator quantum well film, the insulating interlayer, and the second topological insulator quantum well film are lattice-matched with each other, cooperatively forming a heterojunction structure.

3. The double-channel topological insulator structure of claim 1, wherein the first topological insulator quantum well film has a first lattice constant; the insulating interlayer has a second lattice constant; the second topological insulator quantum well film has a third lattice constant; a ratio of the first lattice constant to the second lattice constant is between 1:1.1 and 1.1:1; and a ratio of the second lattice constant to the third lattice constant is between 1:1.1 and 1.1:1.

4. The double-channel topological insulator structure of claim 1, wherein the insulating interlayer is formed on a surface of the first topological insulator quantum well film by molecular beam epitaxy; a difference between a molecular beam epitaxy growth temperature of the insulating interlayer and a molecular beam epitaxy growth temperature of the first topological insulator quantum well film is less than or equal to 100° C.; a difference between the molecular beam epitaxy growth temperature of the insulating interlayer and a molecular beam epitaxy growth temperature of the second topological insulator quantum well film is less than or equal to 100° C.; and a difference between the molecular beam epitaxy growth temperatures of the first and second topological insulator quantum well films is less than or equal to 100° C.

5. The double-channel topological insulator structure of claim 1, wherein a material of the insulating interlayer is selected from wurtzite-structured CdSe, sphalerite-structured ZnTe, sphalerite-structured CdSe, sphalerite-structured CdTe, sphalerite-structured HgSe, or sphalerite-structured HgTe.

6. The double-channel topological insulator structure of claim 1, further comprising an insulating protective layer stacked on the second topological insulator quantum well film.

7. The double-channel topological insulator structure of claim 6, wherein a material of the insulating protective layer is selected from wurtzite-structured CdSe, sphalerite-structured ZnTe, sphalerite-structured CdSe, sphalerite-structured CdTe, sphalerite-structured HgSe, or sphalerite-structured HgTe.

8. The double-channel topological insulator structure of claim 1, wherein the first topological insulator quantum well film has a first coercive field, the second topological insulator quantum well film has a second coercive field, and the first coercive field is larger or smaller than the second coercive field.

9. The double-channel topological insulator structure of claim 8, wherein a material of the first topological insulator quantum well film is represented by a chemical formula M_{y}N_{z}(BiₓSb₁₋ₓ)_{2-y-z}Te₃, and a material of the second topological insulator quantum well film is represented by a chemical formula M′_{y′}N′_{z′}(Bi_{x′}Sb_{1-x′})_{2-y′-z′}Te₃, wherein M, M′, N, N′ are magnetic doping elements; 0<x<, 0≤y, 0≤z, and 0<y+z<2; 0<x′<1, 0≤y′, 0≤z′ and 0<y′+z′<2; x≠x′, y≠y′, and z≠z′.

10. The double-channel topological insulator structure of claim 8, wherein a material of the first topological insulator quantum well film is represented by a chemical formula M_{y}N_{z}(BiₓSb₁₋ₓ)_{2-y-z}Te₃, and a material of the second topological insulator quantum well film is represented by a chemical formula M′_{y′}N′_{z′}(Bi_{x′}Sb_{1-x′})_{2-y′-z′}Te₃, wherein M, M′, N, N′ are magnetic doping elements; 0<x<1, 0≤y, 0≤z, and 0<y+z<2; 0<x′<1, 0≤y′, 0≤z′ and 0<y′+z′<2; x≠x′, y≠y′, or z≠z′.

11. The double-channel topological insulator structure of claim 9, wherein M, M′, N, N′ are independently selected from one of Cr, Ti, Fe, Mn and V.

12. The double-channel topological insulator structure of claim 8, wherein a material of the first topological insulator quantum well film is represented by a chemical formula M_{y}N_{z}(BiₓSb₁₋ₓ)_{2-y-z}Te₃, and a material of the second topological insulator quantum well film is represented by a chemical formula M′_{y′}N′_{z′}(Bi_{x′}Sb_{1-x′})_{2-y′-z′}Te₃, where M, M′, N, N′ are magnetic doping elements; M is different from M′, or N is different from N′; 0<x<1, 0≤y, 0≤z, and 0<y+z<2; 0<x′<1, 0≤y′, 0≤z′ and 0<y′+z′<2.

13. The double-channel topological insulator structure of claim 12, wherein M, M′, N, N′ are independently selected from one of Cr, Ti, Fe, Mn, and V.

14. The double-channel topological insulator structure of claim 1, wherein a thickness of each of the first and second topological insulator quantum well films is in a range from 5 QL to 10 QL.

15. The multi-channel topological insulator structure of claim 1, wherein a thickness of the insulating interlayer is in a range from 0.35 nm to 20 nm.

16. The multi-channel topological insulator structure of claim 1, wherein the first topological insulator quantum well film is Cr_{0.2}V_{0.16}(Bi_{0.34}Sb_{0.66})_{1.82}Te₃, and the second topological insulator quantum well film is Cr_{0.10}V_{0.8}(Bi_{0.44}Sb_{0.56})_{1.82}Te₃.

17. A method for making the double-channel topological insulator structure of claim 1, comprising:
providing the insulating substrate in a molecular beam epitaxy reactor chamber;
growing the first topological insulator quantum well film by molecular beam epitaxy on a surface of the insulating substrate having a first temperature;
growing the insulating interlayer by molecular beam epitaxy on a surface of the first topological insulator quantum well film having a second temperature; and
growing the second topological insulator quantum well film by molecular beam epitaxy on a surface of the insulating interlayer having a third temperature.

18. The method of claim 17, wherein the second temperature is in a range from the first temperature minus 100° C. to the first temperature plus 100° C., and the third temperature is in a range from the first temperature minus 100° C. to the first temperature plus 100° C.

19. The method of claim 17, wherein the first temperature is in a range from 150° C. to 250° C.; the second temperature is in a range from 50° C. to 350° C.; and the third temperature is in a range from 150° C. to 250° C.

20. A method for generating quantum spin Hall effect, comprising:
providing the double-channel topological insulator of claim 8; and
applying a magnetic field which is ranged between the first coercive field and the second coercive field to the double-channel topological insulator.
